(19) United States
(12) Patent Application Publication
(10) Pub. No.: US 2026/0322387 A1
(43) Pub. Date: Oct. 15, 2026

(54) Fixed Rate Link Video Connectivity Circuitry

(71) Applicant: Altera Corporation, San Jose, CA (US)

(72) Inventors: Russell Hicks, Oxfordshire (GB); Jon Harris, Oxfordshire (GB)

(21) Appl. No.: 19/465,862

(22) Filed: Jan. 30, 2026

(51) Int. Cl. H03L 7/085; G05B 19/05; H04N 21/4363

(52) U.S. Cl. CPC H03L 7/085; G05B 19/056; H04N 21/43635

(57) ABSTRACT

To follow video protocols, such as High-Definition Multimedia Interface (HDMI) 2.1 implementation protocols, on a programmable logic device without a dedicated phase-locked loop (PLL) generating a fixed rate link speed clock (FRL clock), a data valid signal may be utilized on the programmable logic device to effectively divide a receiver clock originally set to an FRL clock frequency down through data valid signaling to a frequency compatible for components using a link speed clock frequency to operate. The clocking arrangement may enable FRL video connectivity and Transition Minimized Differential Signaling (TMDS) protocols to be followed on a single device without a dedicated PLL generating an FRL clock.

### BACKGROUND

The present disclosure relates generally to integrated circuit devices. More particularly, the present disclosure relates to circuitry to support communication protocols without an additional phase-locked loop (PLL), such as a PLL that would otherwise be used to generate a fixed rate link (FRL) clock for FRL video connectivity protocols.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Some integrated circuit devices receive or transmit video data for display on an electronic display via a communication protocol. Some communication protocols, such as High-speed High-Definition Multimedia Interface (HDMI) 2.1, use a dedicated fixed rate link (FRL) clock. Many implementations of this protocol generate the dedicated FRL clock via a dedicated phase-locked loop (PLL). In certain instances, this dedicated PLL may limit the number of HDMI interfaces that can be instantiated on an associated integrated circuit device.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1;

FIG. 3 is a block diagram of an HDMI receiver architecture;

FIG. 4 is a block diagram of an HDMI transmitter architecture;

FIG. 5 is a block diagram of physical receiver circuitry and receiver processing circuitry of the HDMI receiver architecture of FIG. 3, using a clocking arrangement in conjunction with data valid signaling that allows FRL video connectivity without a dedicated FRL PLL;

FIG. 6 is a timing diagram of a receiver clock, a receiver data valid signal, and a link speed clock of the architecture of FIG. 5;

FIG. 7 is a block diagram of physical transmitter circuitry and transmitter processing circuitry of the HDMI transmitter architecture of FIG. 4, using a clocking arrangement in conjunction with data valid signaling that allows for FRL video connectivity while utilizing a single transmitter clock to enable both FRL rate processing and output clock rate processing;

FIG. 8 is a timing diagram of the transmitter clock, the transmitter FRL data valid signal, the FRL clock, the transmitter output data valid signal, and the output clock of FIG. 7; and

FIG. 9 is a block diagram of a data processing system that may incorporate the systems and methods of this disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

To preserve die area on an integrated circuit device, this disclosure describes circuitry to support communication protocols without an additional phase-locked loop (PLL). Indeed, the present disclosure describes systems and techniques related to removing a phase-locked loop (PLL) that would otherwise be used to generate a fixed rate link (FRL) clock in FRL video connectivity protocols. The additional PLL may be avoided through the use of data valid signaling and/or clock gating signals.

HDMI receiver architectures may contain various components with different operating clock frequencies. For example, HDMI 2.1 receiver architectures may have a series of components that make up an HDMI 2.1 path for processing data according to HDMI 2.1 protocols. Such HDMI 2.1 paths typically have an initial component that may receive data at a link speed clock frequency and output data at an FRL clock frequency. Subsequent components of the HDMI 2.1 path may generally run at an FRL clock frequency. HDMI 2.1 receiver architectures may also include a series of components that make up a Transition Minimized Differential Signaling (TMDS) path for processing of data according to HDMI 2.0 and older protocols to allow for backwards compatibility. Such components often run at the link speed clock frequency, which has a different frequency than the FRL clock frequency. HDMI receiver architectures traditionally accommodate this difference in operating clock frequencies by having a PLL generate a receiver clock frequency compatible for components that may operate according to the link speed clock frequency, and a separate dedicated FRL clock PLL to generate an FRL clock with a frequency compatible for operation of components that may operate according to the FRL clock frequency. The addition of this separate dedicated FRL PLL limits the number of HDMI interfaces (e.g., transmitters, receivers) that can be instantiated on an associated integrated circuit device. The present disclosure describes a system that allows for HDMI 2.1 receiver implementation without a dedicated FRL clock PLL in order to conserve die area (e.g., space on the integrated circuit device, PLL resources). This may be accomplished by utilizing data valid signaling. More specifically, a single PLL of the receiver circuitry may generate a receiver clock that has a receiver clock frequency that matches the FRL clock frequency. The receiver clock may be received by components of the HDMI 2.1 path and the TMDS path regardless of their operating frequencies. Data valid signaling may then be used to adjust the data rate of data input and/or output from components that may have operating frequencies different than the receiver clock frequency. As such, components that may operate according to the FRL clock frequency may operate properly utilizing the receiver clock which has a receiver clock frequency matching the FRL clock frequency, while components that may operate according to the link speed clock frequency may operate properly utilizing the receiver clock in conjunction with data valid signaling to adjust the flow of data and thereby compensate for the difference between the receiver clock frequency such components have received and the link speed clock frequency such components may operate according to.

Similarly, some HDMI transmitter architectures may contain various components with different operating clock frequencies. For example, HDMI 2.1 transmitter architectures may have one or more components that may perform video data processing according to an FRL clock frequency. Additionally, it is also common for HDMI 2.1 transmitter architectures to have one or more components that may provide resampled video data at an output clock frequency (e.g., a symbol rate clock frequency). In many instances, the output clock frequency and the FRL clock frequency may be different. Typically, HDMI 2.1 transmitter architectures accommodate this difference in operating clock frequencies by having a dedicated FRL clock PLL generate an FRL clock with an FRL clock frequency that is used for components that may operate according to the FRL clock frequency. Similarly to the situation described with regard to typical HDMI receiver architectures, the addition of a separate dedicated FRL clock PLL limits the number of HDMI interfaces (e.g., transmitters, receivers) that can be instantiated on an associated integrated circuit device. The present disclosure aims in part to develop a system that allows for HDMI 2.1 transmitter implementation without a dedicated FRL clock PLL in order to conserve die area (e.g., space on the integrated circuit). This may be accomplished by via data valid signaling. More specifically, a single PLL of the transmitter circuitry may generate a transmitter clock that has a transmitter clock frequency (e.g., a pixel clock frequency) that may be different than the FRL clock frequency and the output clock frequency. The transmitter clock may then be received by components of the HDMI 2.1 transmitter architecture that may operate according to an FRL clock frequency. Data valid signaling may then be used to adjust the data rate of the data input and/or output from components of the HDMI 2.1 transmitter architecture that may operate according to the FRL clock frequency. As such, components of the HDMI 2.1 architecture that may operate according to the FRL clock frequency may operate properly utilizing the transmitter clock in conjunction with data valid signaling to adjust the flow of data and thereby compensate for the difference between the transmitter clock frequency such components have received and the FRL clock frequency such components may operate according to. The transmitter clock may also be received directly by a clock divider that may divide the transmitter clock down to be received by components of the HDMI 2.1 architecture that may operate according to the output clock frequency.

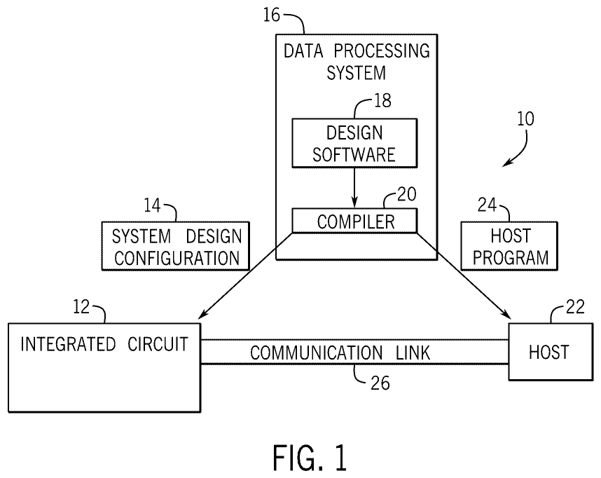

With the foregoing in mind, FIG. 1 illustrates a block diagram of a system 10 that may be used to program an integrated circuit device 12, such as an FPGA (e.g., Agilex™, Stratix®, Arria®, MAX®, or Cyclone® devices by Altera® Corporation), with such a system design using a system design configuration 14. Note that, while this disclosure largely refers to the integrated circuit device 12 as being a programmable logic device, such as an FPGA, in some embodiments, the integrated circuit device 12 may also include a one-time programmable device or structured application specific integrated circuit (ASIC), such as an Altera® eASIC™ device by Altera® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design configuration 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are necessary to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit device 12.

Additionally or alternatively, the host 22 running the host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting. The integrated circuit device 12 may take any suitable form that may implement the system design configuration 14.

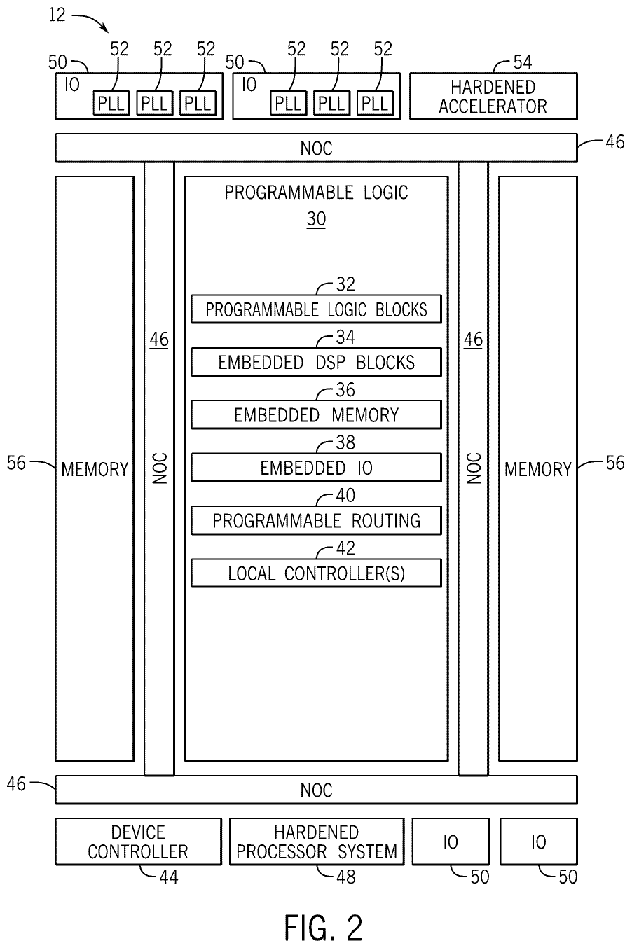

FIG. 2 illustrates a block diagram of an example integrated circuit device such as the integrated circuit device of FIG. 1. As shown in FIG. 2, the integrated circuit device 12 may include programmable logic circuitry 30, which include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any the programmable logic blocks 32 to implement any desired logic circuitry with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 kB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed by corresponding local controllers 42 (e.g., sometimes referred to as Local Sector Managers (LSMs)). The grouping of the programmable logic circuitry 30 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit device 12. The device controller 44 may include any suitable logic circuitry to control and/or program the programmable logic circuitry 30 or other elements of the integrated circuit device 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit device 12.

A network-on-chip (NOC) 46 may connect the various elements of the integrated circuit device 12. The NOC 46 may provide rapid, packetized communication to and from the programmable logic circuitry 30 and other blocks, such as a hardened processor system 48, high-speed input-output (IO) blocks 50, a hardened accelerator 54, and local device memory 56. The integrated circuit device 12 may include the hardened processor system 48 when the integrated circuit device 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The high-speed IO blocks 50 may enable communication using any suitable communication protocol(s) with other devices outside of the integrated circuit device 12, such as a separate memory device. The high-speed IO blocks 50 may contain one or more phase-locked loops (PLLs) 52 each capable of taking in an input reference clock and outputting an output clock that is phase-locked to the reference clock, thereby producing a stable clock signal. Although not shown, there may be PLLs 52 distributed elsewhere on the integrated circuit device 12, such as in the programmable logic circuitry 30. The hardened accelerator 54 may include any hardened application-specific integrated circuitry (ASIC) logic to perform a desired acceleration function. For example, the hardened accelerator 54 may include hardened circuitry to perform cryptographic or media encoding or decoding. The memory 56 may provide local device memory (e.g., cache) that may be readily accessible by the programmable logic circuitry 30.

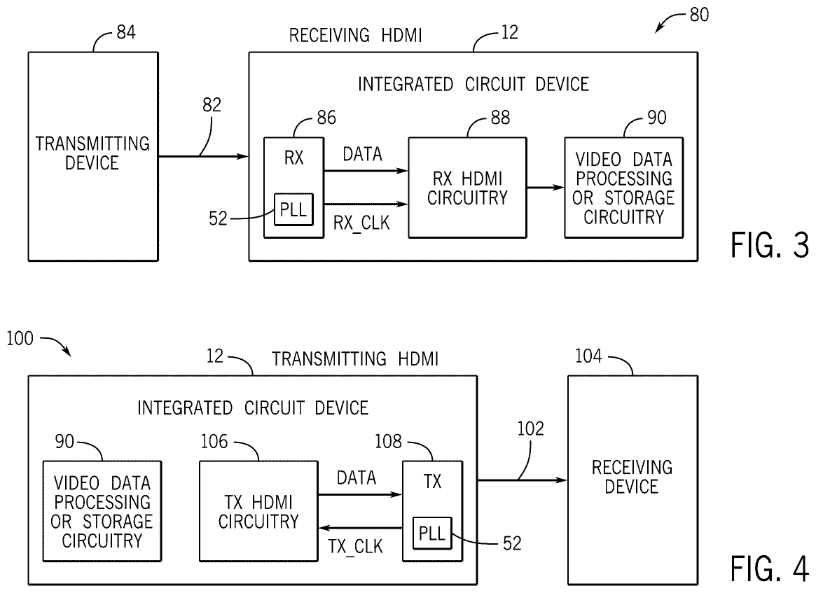

FIG. 3 illustrates a block diagram of an HDMI receiver architecture 80 in accordance with an embodiment of the present disclosure. The HDMI receiver architecture 80 may include a transmitting device 84 and the integrated circuit device 12. The transmitting device 84 may be a computer, media player, gaming console, digital camera, or any other type of device with an HDMI output. The transmitting device 84 may transmit data 82 to the integrated circuit device 12. More specifically, the transmitting device 84 may transmit data 82 to physical receiver circuitry 86 of the integrated circuit device 12. The data 82 may be digital video data, digital audio data, and/or other types of data suitable to be sent to HDMI receivers. In certain embodiments, the physical receiver circuitry 86 may be in one or more of the high-speed IO blocks 50.

The integrated circuit device 12 may also include receiver processing circuitry 88 that may receive data 82 from the physical receiver circuitry 86 and process the data 82 into video data. In certain embodiments, at least a portion of the receiver processing circuitry 88 may operate according to a fixed rate link (FRL) clock frequency. Further, in certain embodiments, at least a portion of the receiver processing circuitry 88 may operate according to a link speed clock frequency that may have a different frequency than the FRL clock frequency. However, in accordance with various embodiments detailed below, the portion of the receiver processing circuitry 88 that may operate according to an FRL clock frequency and the portion of the receiver processing circuitry 88 that may operate according to the link speed clock frequency may both perform respective functions using a receiver clock generated from the PLL 52. In some embodiments, at least a portion of the receiver processing circuitry 88 may process the data 82 into video data based on a High-Definition Multimedia Interface (HDMI) 2.1 protocol (e.g., an HDMI 2.1 protocol) that specifies the FRL clock frequency. Further, in certain embodiments, the receiver clock may have a frequency that is higher, lower, or equal to the FRL clock frequency. The receiver processing circuitry 88 may then transmit the video data to video data processing or storage circuitry 90 that may utilize the video data.

FIG. 4 illustrates a block diagram of an HDMI transmitter architecture 100 in accordance with an embodiment of the present disclosure. The HDMI transmitter architecture 100 may include the integrated circuit device 12 and a receiving device 104. The receiving device 104 may be a television, monitor, projector, or any other type of device with an HDMI input. The integrated circuit device 12 may include physical transmitter circuitry 108 that may transmit output data 102 to the receiving device 104. The output data may be digital video data, digital audio data, and/or other types of data suitable to be received by the receiving device 104. The physical transmitter circuitry 108 may transmit the output data 102 to the receiving device 104 based on an output clock frequency (e.g., a symbol rate clock frequency). The physical transmitter circuitry 108 may also generate a transmitter clock (e.g., a pixel rate clock) that may be generated from a phase-locked loop (PLL) 52. Further, the physical transmitter circuitry 108 may be in one or more of the high-speed IO blocks 50.

The integrated circuit device 12 may also include transmitter processing circuitry 106 that may perform video data processing. The transmitter processing circuitry 106 may receive data from the video data processing or storage circuitry 90, and output data to the physical transmitter circuitry 108. In certain embodiments, at least a portion of the transmitter processing circuitry 106 may operate according to an FRL clock frequency. Further, in certain embodiments, at least a portion of the transmitter processing circuitry 106 may provide resampled output data according to an output clock frequency (e.g., a symbol rate clock frequency). However, the portion of the transmitter processing circuitry 106 that may operate according to an FRL clock frequency and the portion of the transmitter processing circuitry 106 that may provide resampled output data according to an output clock frequency may both perform respective functions using the transmitter clock generated from the PLL 52. In some embodiments, at least a portion of the transmitter processing circuitry 106 may perform video processing based on an HDMI protocol (e.g., HDMI 2.1 protocol) that specifies the FRL clock frequency. In certain embodiments, the transmitter clock may have a frequency that is higher, lower, or equal to the FRL clock frequency. Additionally, in certain embodiments, the transmitter clock may have a frequency that is higher, lower, or equal to the output clock frequency.

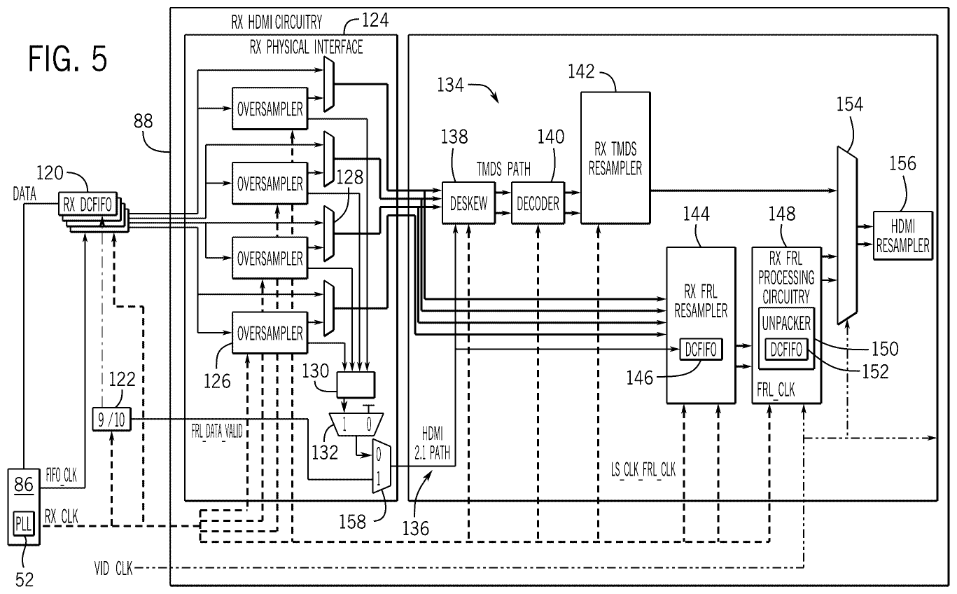

FIG. 5 illustrates a block diagram of the physical receiver circuitry 86 and the receiver processing circuitry 88 of the HDMI receiver architecture 80. As shown in FIG. 5, the clocking arrangement in conjunction with data valid signaling allows FRL video connectivity protocol to be followed without a dedicated FRL PLL.

As previously discussed, the physical receiver circuitry 86 may include a PLL 52 capable of generating a receiver clock. More specifically, the PLL 52 may take in an input reference clock from an external source and output a clock that is phase-locked to the reference clock, thereby producing a stable clock signal (e.g., the receiver clock).

The physical receiver circuitry 86 may send data to one or more receiver dual-clock FIFOs (DCFIFOs) 120. The data sent by the physical receiver circuitry 86 to the 120 may be parallel data. In the illustrated example, four streams of parallel data may be sent to a respective one of the receiver DCFIFOs 120, but there may be more or fewer streams. The receiver DCFIFOs 120 may serve as a data buffer that enables the transfer of data between multiple components with varying clock frequencies. For example, in certain embodiments, the data being transferred from the physical receiver circuitry 86 to the receiver DCFIFOs 120 may have a clock embedded in it that is asynchronous with the clock that one or more portions of the receiver processing circuitry 88 operates on. The receiver DCFIFOs 120 may write the data at a recovered clock rate corresponding to the clock embedded in the data and read the data at a rate corresponding to a link speed clock, which may be compatible for downstream components of the receiver processing circuitry 88. Further, the receiver DCFIFOs 120 may output data into data segments. For example, in certain embodiments, the physical receiver circuitry 86 may send parallel data to four receiver DCFIFOs 120 each of which may output data into segments of 40 bits for a total of 160 bits.

The data segments that are output from the one or more receiver DCFIFOs 120 may be sent to an HDMI receiver physical interface 124. The HDMI receiver physical interface 124 may include zero or more receiver oversamplers 126 each of which may receive a respective stream of data segments output from the one or more receiver DCFIFOs 120. In certain embodiments, oversampling may be performed by the receiver oversamplers 126 in instances where data being received is below a minimum data rate of at least a portion of the receiver processing circuitry 88. The oversampling factor of the receiver oversamplers 126 may be of various values. Further, in certain embodiments the receiver oversamplers 126 may operate according to the link speed clock. Oversampled data from each of the receiver oversamplers 126 may be output to a respective multiplexer of one or more receiver multiplexers 128 contained within the HDMI receiver physical interface 124 as a first receiver multiplexer input. Each of the receiver multiplexers 128 may also receive data segments directly from a respective receiver DCFIFO of the receiver DCFIFOs 120 as a second receiver multiplexer input such that the oversampling process may be bypassed. Each of the receiver multiplexers 128 may output one of the two receiver multiplexer inputs at a time (e.g., switch between outputting one of either the oversampled data segments or non-oversampled data segments). For example, in instances where the data being received is below a minimum data rate of at least a portion of the receiver processing circuitry 88, the output of the receiver multiplexers 128 may be set such that the receiver multiplexers 128 output oversampled data segments. As another example, in instances where the data being received is not below a minimum data rate of at least a portion of the receiver processing circuitry 88, the output of the receiver multiplexers 128 may be set such that the receiver multiplexers 128 output non-oversampled data segments.

The HDMI receiver physical interface 124 may also include a validation block 130 that may control flow of the data to downstream components of the receiver processing circuitry 88. More specifically, the validation block 130 may receive valid signals from each of the receiver oversamplers 126. In instances where all of the receiver oversamplers 126 output a valid signal, the validation block 130 may output a valid signal that may serve as a first input into an oversampler multiplexer 132, which will be discussed in greater detail below.

In certain embodiments, the receiver processing circuitry 88 may also include two paths to process the data from the HDMI receiver physical interface 124 into video data in accordance with various data processing protocols. For example, as illustrated, the receiver processing circuitry 88 may include a Transition-Minimized Differential Signaling (TMDS) path 134 to process data received from the HDMI receiver physical interface 124 into video data. The TMDS path 134 may be utilized according to various older HDMI version protocols including HDMI versions 1.0, 1.1, 1.2, 1.2a, 1.3, 1.3a, 1.3b, 1.3b1, 1.3c, 1.4, 1.4a, 1.4b, 2.0, 2.0a, and 2.0b. The receiver processing circuitry 88 may also include an HDMI 2.1 path 136 for processing data received from the HDMI receiver physical interface 124 into video data according to HDMI version 2.1 protocol.

As depicted, the TMDS path 134 may utilize three data channels transmitting data from a respective receiver multiplexer of the receiver multiplexers 128, but there may be more or fewer data channels. The TMDS path 134 may include a TMDS deskew block 138 that may synchronize incoming parallel data channels to ensure data integrity. This process addresses the problem of varying propagation delays or “skew” between the incoming parallel data channels. As an example, this “skew” may occur as a result of manufacturing variances in cables or connectors. In certain embodiments, the TMDS deskew block 138 may operate according to a link speed clock frequency.

The TMDS path 134 may also include a TMDS decoder 140 that may convert the received data channels that may have previously been encoded into data that is useable for downstream components of the receiver processing circuitry 88. For example, the TMDS decoder 140 may receive the incoming parallel data channels which may include 10-bit symbols and decode the 10-bit symbols back into 8-bit data bytes. In certain embodiments, the TMDS decoder 140 may operate according to a link speed clock frequency. The TMDS path 134 may also include a TMDS resampler 142 that may resample the decoded data. More specifically, the TMDS resampler 142 may include a DCFIFO that may serve as a data buffer enabling the transfer of data between multiple components of the receiver processing circuitry 88 with varying clock frequencies. For example, in certain embodiments, the incoming parallel data being received by the TMDS resampler 142 from the TMDS decoder 140 may be received at a link speed clock frequency and may be output out of the TMDS resampler 142 at a video clock frequency suitable for downstream components of the receiver processing circuitry 88. In certain embodiments, the video clock frequency may correspond to a native refresh rate of a downstream display.

As previously discussed, the receiver processing circuitry 88 may also include an HDMI 2.1 path 136 for processing data into video data in HDMI version 2.1 protocols. As depicted, the HDMI 2.1 path 136 may utilize four data channels transmitting data from a respective receiver multiplexer of the receiver multiplexers 128, but there may be more or fewer data channels.

The HDMI 2.1 path 136 may include a receiver FRL resampler 144 that may resample incoming parallel data channels. More specifically, the receiver FRL resampler 144 may include a receiver FRL DCFIFO 146 that may serve as a data buffer enabling the transfer of data between multiple components of the receiver processing circuitry 88 with varying clock frequencies. For example, in certain embodiments, the incoming parallel data being received by the receiver FRL resampler 144 from the receiver multiplexers 128 may be received at a link speed clock frequency and may be output of the receiver FRL resampler 144 at an FRL clock frequency suitable for receiver FRL processing circuitry 148.

The HDMI 2.1 path 136 may also include the aforementioned receiver FRL processing circuitry 148, which may serve multiple processing functions. For example, the receiver FRL processing circuitry 148 may perform forward error correction that may detect and correct transmission errors in the incoming parallel data channels. The receiver FRL processing circuitry 148 may also include an unpacker block 150 that may convert the data width of received data into a data width suitable for downstream components of the receiver processing circuitry 88. The receiver FRL processing circuitry 148 may also include a receiver FRL processing circuitry DCFIFO 152 that may serve as a data buffer enabling the transfer of data between multiple components of the receiver processing circuitry 88 with varying clock frequencies. For example, in certain embodiments, the receiver FRL processing circuitry 148 may perform operations according to an FRL clock frequency and may output the parallel data channels at the video clock frequency, which may be suitable for downstream components of the receiver processing circuitry 88.

In certain embodiments, the data output of both the TMDS path 134 and the HDMI 2.1 path 136 may serve as inputs for a receiver output multiplexer 154 that may output one of the two multiplexer inputs at a time. Thus, the receiver output multiplexer 154 may switch between the output of the TMDS path 134 and the HDMI 2.1 path 136 to allow for backwards compatibility. The data output of the receiver output multiplexer 154 may then be sent to a receiver HDMI resampler 156 that may resample data to a format suitable to be sent to the video data processing or storage circuitry 90. The receiver HDMI resampler 156 may then output the data to the video processing or storage circuitry 90.

With the foregoing in mind, it may be appreciated that at least a portion of the receiver processing circuitry 88 may operate according to an FRL clock frequency, while a remaining portion of the receiver processing circuitry 88 may operate according to a clock frequency that is different than the FRL clock frequency (e.g., the link speed clock frequency). For example, in certain embodiments, the receiver FRL resampler 144 and the receiver FRL processing circuitry 148 (e.g., the receiver FRL processing logic) may both perform certain operations described above according to an FRL clock frequency of 333 MHz while other components of the receiver processing circuitry 88 may operate according to the link speed clock, which may have a frequency other than 333 MHz. In existing HDMI receiver architectures, this difference in operating clock frequencies is accommodated for by having a PLL of the physical receiver circuitry generate a receiver clock frequency compatible for components of receiver processing circuitry that may operate according to a link speed clock frequency, and a dedicated FRL clock PLL to generate an FRL clock signal with a frequency compatible for operation of components of receiver processing circuitry that may operate according to an FRL clock frequency. However, in accordance with this disclosure, the portion of the receiver processing circuitry 88 that may operate according to an FRL clock frequency may process the data 82 into video data using the receiver clock generated from the PLL 52 as opposed to a dedicated FRL clock signal from an additional PLL. This may be accomplished through the use of a receiver data valid signal 122 in conjunction with the validation block 130, the oversampler multiplexer 132, and/or an FRL multiplexer 158.

In certain embodiments, the receiver clock generated from the PLL 52 of the physical receiver circuitry 86 may have a frequency that matches the FRL clock frequency compatible for components of the receiver processing circuitry 88 that operate according to the FRL clock frequency. The receiver clock may be received by components of the receiver processing circuitry 88 that may perform operations according to the FRL clock frequency and received by components of the receiver processing circuitry 88 that may perform operations according to the link speed clock frequency. To accommodate components of the receiver processing circuitry 88 that operate according to the link speed clock frequency, a receiver data valid signal 122 may be utilized in conjunction with the validation block 130, the oversampler multiplexer 132, and/or the FRL multiplexer 158 to adjust the data rate of data input and/or output from such components. As such, components that may operate according to the FRL clock frequency may operate properly by utilizing the receiver clock which has a receiver clock frequency corresponding to the FRL clock frequency. Components that may operate according to the link speed clock frequency may operate properly utilizing the receiver clock in conjunction with data valid signaling to adjust the flow of data and thereby compensate for the difference between the receiver clock frequency such components have received and the link speed clock frequency such components may operate according to. Such data valid signaling may be propagated via the receiver data valid signal 122, which may be used in conjunction with the validation block 130, the oversampler multiplexer 132, and/or the FRL multiplexer 158. Such data valid signaling may effectively convert the receiver clock, which may originally match the FRL clock frequency, down to a clock frequency that matches the operating frequency of components that may perform operations at a link speed clock frequency.

In the illustrated embodiment, the receiver data valid signal 122 is set to 9/10 such that any data impacted by the data valid signal 122 may be valid 90% of the time and therefore may have a data rate that is reduced by 10%. Thus, at any components that have received the receiver clock and are impacted by the data valid signal 122, the receiver clock frequency may be effectively reduced by 10% to the link speed clock frequency. As an example, this clocking/data valid configuration would allow for accommodation of components that may operate according to an average FRL clock frequency of approximately 333 MHz and components that may operate at an average link speed clock frequency of approximately 300 MHz without a dedicated FRL clock PLL. In various embodiments, the receiver data valid signal 122 may be set to any ratio to accommodate portions of the receiver processing circuitry 88 with varying differences between respective operating clock frequencies.

In the illustrated embodiment, the receiver clock and the receiver data valid signal 122 may be received by the one or more receiver DCFIFOs 120. As previously mentioned, the receiver DCFIFOs 120 may write data at a recovered clock rate corresponding to the clock embedded in the data and read the data at a rate corresponding to the link speed clock, which may be compatible for downstream components of the receiver processing circuitry 88. Despite receiving the receiver clock which may have a frequency matching the FRL clock frequency, the receiver DCFIFOs 120 may still read the data at a rate corresponding to the link speed clock because of the data valid signal 122. For example, the receiver clock frequency (e.g., the FRL clock frequency) may be approximately 333 MHz while the link speed clock frequency is approximately 300 MHz. In such an embodiment, the receiver DCFIFOs 120 may use the receiver data valid signal 122, which may be set to 9/10ths, to read the data at the link speed clock rate which may be suitable for components of the HDMI receiver physical interface 124. This is because although the receiver clock being received by the receiver DCFIFOs 120 may be 333 MHz, the receiver DCFIFOs 120 may read the data at approximately 300 MHZ because the data may be valid 90% of the time and 300 MHZ is approximately 90% of 333 MHz. It may be appreciated that in various embodiments, the frequency of the receiver clock and/or the valid ratio of the receiver data valid signal 122 may be varying values in order to accommodate portions of the receiver processing circuitry 88 with varying differences between respective operating clock frequencies.

As further illustrated, the receiver oversamplers 126 may receive the receiver clock. As previously mentioned, the receiver oversamplers 126 may operate according to the link speed clock. Despite receiving the receiver clock which may have a frequency matching the FRL clock frequency, the receiver oversamplers 126 may still operate according to the link speed clock because the data being received by the receiver oversamplers 126 from the receiver DCFIFOs 120 is being read by the receiver DCFIFOs 120 at a rate corresponding to the link speed clock due to the utilization of the data valid signal 122, as described above.

As further depicted, the receiver data valid signal 122 may also be sent to the FRL multiplexer 158 to serve as a first FRL multiplexer input. The FRL multiplexer 158 may also receive an output from the oversampler multiplexer 132 to serve as a second FRL multiplexer input. The FRL multiplexer 158 may output one of the two FRL multiplexer inputs at a time (e.g., switch between one of either the receiver data valid signal 122 or the output of the oversampler multiplexer 132). For example, in instances wherein the HDMI 2.1 path 136 is to be utilized (e.g., FRL mode), the FRL multiplexer 158 may output the receiver data valid signal 122. As another example, in instances wherein the TMDS path 134 is to be utilized (e.g., TMDS mode), the FRL multiplexer 158 may output the output of the oversampler multiplexer 132.

As previously mentioned, the validation block 130 may receive valid signals from each of the receiver oversamplers 126. In instances where all of the receiver oversamplers 126 output a valid signal, the validation block 130 may output a valid signal that may serve as a first input into the oversampler multiplexer 132. As illustrated, the oversampler multiplexer 132 may also receive a logic high signal (e.g., logic 1, condition is true) as a second input into the oversampler multiplexer 132. The oversampler multiplexer 132 may output one of the two oversampler multiplexer inputs at a time (e.g., switch between one or either the output of the validation block 130 or the logic high signal). For example, in instances wherein oversampling at the receiver oversamplers 126 is desired as described above, the oversampler multiplexer 132 may output the output of the validation block 130 to the FRL multiplexer 158. As another example, in instances wherein oversampling at the receiver oversamplers 126 is bypassed as described above, the oversampler multiplexer 132 may output the logic high signal (e.g., logic 1, condition is true) to the FRL multiplexer 158.

It may be appreciated that such a configuration of the data valid signal 122, the validation block 130, the oversampler multiplexer 132, and the FRL multiplexer 158 may enable downstream components of the receiver processing circuitry 88 that may perform operations according to the FRL clock frequency and downstream components of the receiver processing circuitry 88 that may perform operations according to the link speed clock frequency to be accommodated for while each receiving the receiver clock which may have a receiver clock frequency that corresponds to the FRL clock frequency.

In the illustrated embodiment, the receiver clock may be received by the receiver FRL resampler 144 and the FRL processing circuitry 148. As previously discussed, the FRL resampler 144 may receive incoming parallel data from the receiver multiplexers 128 at a link speed clock frequency and may output the parallel data to the FRL processing circuitry 148 at an FRL clock frequency. While the operating speed of the outputting operation performed by the FRL resampler 144 may be accommodated for solely by the receiver clock, the inputting operation performed by the FRL resampler 144 may not be accommodated for solely by the receiver clock. Despite receiving the receiver clock which may have a frequency that corresponds to the FRL clock frequency, the FRL resampler 144 may still receive incoming parallel data from the receiver multiplexers 128 at the link speed clock frequency because of the receiver data valid signal 122 which has been output from the FRL multiplexer 158. For example, the receiver clock frequency (e.g., the FRL clock frequency) may be approximately 333 MHz while the link speed clock frequency is approximately 300 MHz. In such an embodiment, the FRL resampler 144 may use the receiver data valid signal 122 output from the FRL multiplexer 158 when the HDMI 2.1 path 136 is in use, which may be set to 9/10ths, to receive the incoming parallel data from the receiver multiplexers 128 at the link speed clock rate. In the illustrated embodiment, the output operation of the FRL resampler 144 and the previously discussed input operation of the FRL processing circuitry 148 may be properly performed at the FRL clock frequency utilizing the received receiver clock which may have a receiver clock frequency that corresponds to the FRL clock frequency. It should be noted that the above example is in accordance with the illustrated embodiment. As such, the associated ratios of valid signaling may be increased or decreased to accommodate portions of the receiver processing circuitry 88 with varying differences between respective operating clock frequencies.

As further illustrated, the receiver clock may be received by the TMDS deskew block 138, the TMDS decoder 140, and the TMDS resampler 142. As previously discussed, the TMDS deskew block 138, the TMDS decoder 140, and the TMDS resampler 142 may perform respective operations according to the link speed clock frequency. More specifically, such components may perform respective operations within a range of frequencies that may be capped at the link speed clock frequency. Despite receiving the receiver clock which may have a frequency that corresponds to the FRL clock frequency, the TMDS deskew block 138, the TMDS decoder 140, and the TMDS resampler 142 may still perform respective operations at an appropriate frequency because of the output of the oversampler multiplexer 132. As previously discussed, when in instances wherein the TMDS path 134 is to be utilized (e.g., TMDS mode), the FRL multiplexer 158 may output the output of the oversampler multiplexer 132. Further, as previously discussed, the output of the oversampler multiplexer 132 may be dictated based on whether oversampling at the receiver oversamplers 126 is to be bypassed or not. It may be appreciated that in instances where oversampling at the receiver oversamplers 126 is bypassed, such oversampling is bypassed because the data being received is above a minimum data rate of the components of the TMDS path 134 (e.g., the TMDS deskew block 138, the TMDS decoder 140, the TMDS resampler 142). As previously discussed, in such instances, the output of the oversampler multiplexer 132 may be the logic high signal (e.g., logic 1, condition is true). Because the data being received is above the minimum data rate of the components of the TMDS path 134, the output of the oversampler multiplexer 132 and therefore the output of the FRL multiplexer 158 may be the logic high signal (e.g., logic 1, condition is true) to accommodate the operating frequencies of the components of the TMDS path 134 despite the components of the TMDS path 134 receiving the receiver clock which may have a receiver clock frequency that corresponds to the FRL clock frequency. It may be further appreciated that in instances where oversampling at the receiver oversamplers 126 is not bypassed, such oversampling is not bypassed because the data being received is below the minimum data rate of the components of the TMDS path 134 (e.g., the TMDS deskew block 138, the TMDS decoder 140, the TMDS resampler 142). As previously discussed, in such instances, the output of the oversampler multiplexer 132 may be the output of the validation block 130 which may output a valid signal in instances where all of the receiver oversamplers 126 output a valid signal. Because the data validation block 130 only outputs a valid signal when all of the receiver oversamplers 126 output a valid signal, when in oversampling mode the output of the oversampler multiplexer 132 and therefore the output of the FRL multiplexer 158 may be the output of the data validation block 130 to accommodate the operating frequencies of the components of the TMDS path 134 despite the components of the TMDS path 134 receiving the receiver clock which may have a receiver clock frequency that corresponds to the FRL clock frequency.

In certain embodiments, the receiver clock may originally have a frequency that corresponds to the operating frequency of components of the receiver processing circuitry 88 that may operate according to a link speed clock frequency. In such instances, the receiver data valid signal 122 may adjust the data rate of data being input and/or output of components of the receiver processing circuitry 88 that may perform operations according to the FRL clock frequency.

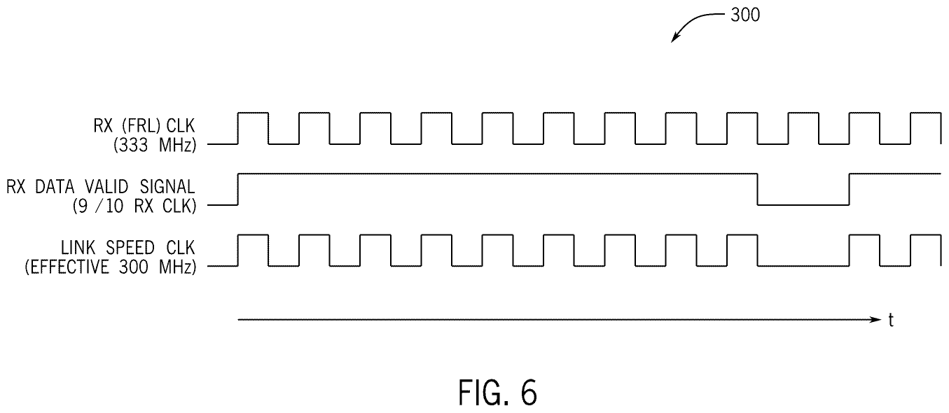

FIG. 6 is a receiver timing diagram 300 of the receiver clock, the receiver data valid signal 122, and the effective link speed clock of FIG. 5, in accordance with an embodiment of the present disclosure. As depicted, the receiver clock generated from the PLL 52 may have a frequency of 333 MHz. This receiver clock frequency may correspond to the FRL clock frequency compatible for operation of at least a portion of the receiver processing circuitry 88, as described with reference to FIG. 5. As further illustrated, the receiver data valid signal 122 may output a signal that is valid 9/10ths of the time. When the receiver clock is effectively converted to the effective link speed clock by the receiver data valid signal 122 as described above, the receiver clock frequency may be effectively transformed into the depicted effective link speed clock frequency, which in actuality is indicative of a data rate. Thus, the link speed clock may be effectively derived from the receiver clock. More specifically, the receiver clock frequency may be effectively reduced by 10% to an effective average link speed clock frequency of 300 MHz.

It should be noted that the receiver clock frequency, the effective link speed clock frequency, and the receiver data valid signal 122 ratio depicted in FIG. 6 are merely provided as an example. As such, the receiver clock frequency may be any suitable frequency for operation of FRL processing components such as the inputting operation of the receiver FRL processing circuitry 148, for example. The link speed clock frequency may be any suitable frequency for operation of components of the receiver processing circuitry 88 that operate according to a link speed clock, such as the inputting operation of the FRL resampler 144. Further, the receiver data valid signal 122 ratio may be any ratio suitable for effective clock frequency conversion according to portions of the receiver processing circuitry 88 with varying differences between respective operating clock frequencies.

Further, it may be appreciated that the use of the word “effective” when describing the effective link speed clock that may be derived from the receiver clock is merely intended to illustrate how the data valid signaling adjusts the data rate of data flowing into and out of components of the receiver processing circuitry 88 so that such components may operate according to a link speed clock while receiving the receiver clock which may have a frequency corresponding to the FRL clock frequency.

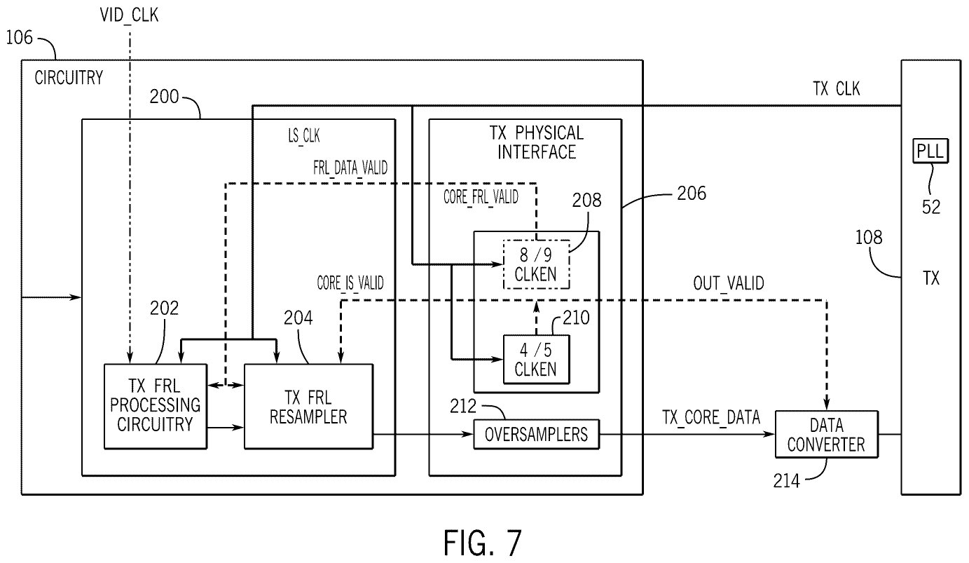

FIG. 7 is a block diagram of the physical transmitter circuitry 108 and the transmitter processing circuitry 106 of the HDMI transmitter architecture 100 of FIG. 4, wherein the clocking/data valid signaling arrangement allows for FRL video connectivity protocol to be followed by deriving an effective FRL clock and an effective output clock from a single transmitter clock, in accordance with an embodiment of the present disclosure.

As previously discussed, the physical transmitter circuitry 108 may include a phase-locked loop (PLL) 52 capable of generating a transmitter clock (e.g., a pixel clock). More specifically, the PLL 52 may take in an input reference clock from an external source and output a clock that is phase-locked to the reference clock, thereby producing a stable clock signal (e.g., the transmitter clock). The physical transmitter circuitry 108 may also transmit data to the receiving device 104 based on an output clock.

The transmitter processing circuitry 106 may include a transmitter FRL processing block 202 that may receive data from the video data processing or storage circuitry 90 according to the video clock frequency and output processed data at the FRL clock frequency. The transmitter processing circuitry 106 may perform an operation that are essentially inverse operations to that of the receiver FRL processing circuitry 148.

The transmitter processing circuitry 106 may also include a transmitter FRL resampler 204 subsequent to the transmitter FRL processing block 202 that may receive processed data from the transmitter FRL processing block 202 according to an FRL clock frequency and may send resampled output data according to an output clock (e.g., a symbol rate clock) frequency to one or more transmitter oversamplers 212 of a transmitter physical interface 206. More specifically, the transmitter FRL resampler 204 may include a DCFIFO that may serve as a data buffer enabling the transfer of data from the FRL clock frequency domain to the output clock frequency domain. The transmitter oversamplers 212 may receive the resampled output data and improve the signal quality of the output data. Oversampled data from the transmitter oversamplers 212 may then be received by a data converter block 214 that may convert the oversampled data into a format suitable to be sent to the physical transmitter circuitry 108.

As previously discussed, at least a portion of the transmitter processing circuitry 106 may operate according to an FRL clock frequency and at least a portion of the transmitter processing circuitry 106 may provide resampled output data according to an output clock frequency. For example, in certain embodiments, the transmitter FRL processing block 202 may receive video data according to a video clock frequency and provide processed video data at an FRL clock frequency of 333 MHz. Further, as an example, a transmitter FRL resampler 204 may receive initially processed video data from the transmitter FRL processing block 202 according to an FRL clock frequency of 333 MHz and provide resampled video data at an output clock frequency of 300 MHz. In existing HDMI transmitter architectures, this difference in operating clock frequencies is accommodated for by having a PLL of the physical transmitter circuitry generate a transmitter clock with a transmitter clock frequency that is then gated down by a clock gating signal to generate an output clock, and a separate dedicated FRL clock PLL to generate an FRL clock signal with a frequency compatible for operation of components that may operate according to an FRL clock frequency. However, in present embodiments, components of the transmitter processing circuitry 106 that may perform operations according to an FRL clock frequency may perform such operations using the transmitter clock generated from the PLL 52 as opposed to a dedicated FRL clock signal from an additional PLL. This may be accomplished through the use of transmitter FRL data valid signal circuitry 208 and transmitter output data valid signal circuitry 210.

In certain embodiments, the transmitter clock generated from the PLL 52 of the physical transmitter circuitry 108 may have a frequency that is different from the FRL clock frequency and the output clock frequency.

As illustrated, the transmitter clock may be received by the transmitter FRL processing block 202 and the transmitter FRL resampler 204. As previously discussed, the transmitter FRL processing block 202 may receive data from the video data processing or storage circuitry 90 according to the video clock frequency and output processed data to the transmitter FRL resampler 204 at the FRL clock frequency. Despite receiving the transmitter clock which may have a frequency that does not correspond to the FRL clock frequency, the transmitter FRL processing block 202 may still output processed data to the transmitter FRL resampler 204 at the FRL clock frequency because of the transmitter FRL data valid signal circuitry 208. For example, the transmitter clock frequency may be approximately 375 MHZ while the FRL clock frequency is approximately 333 MHz. In such an embodiment, the transmitter FRL processing block 202 may use the transmitter FRL data valid signal circuitry 208, which may be set to 8/9ths, to output processed data to the transmitter FRL resampler 204 at the FRL clock frequency. This is because although the transmitter clock being received by the transmitter FRL processing block 202 may be 375 MHz, the transmitter processing block 202 may output processed data to the transmitter FRL resampler 204 at approximately 333 MHz because the data may be valid approximately 88.88% of the time and 333 MHz is approximately 88.88% of 375 MHz. It may be appreciated that in various embodiments, the frequency of the transmitter clock and/or the valid ratio of the transmitter FRL data valid signal circuitry 208 may be varying values in order to accommodate portions of the transmitter processing circuitry 106 with varying differences between respective operating clock frequencies.

Also as previously discussed, the transmitter FRL resampler 204 may receive initially processed video data from the transmitter FRL processing block 202 according to an FRL clock frequency. Despite receiving the transmitter clock which may have a frequency that does not correspond to the FRL clock frequency, the transmitter FRL resampler 204 may still receive initially processed video data from the transmitter FRL processing block 202 at the FRL clock frequency because of the transmitter FRL data valid signal circuitry 208. For example, the transmitter clock frequency may be approximately 375 MHz while the FRL clock frequency is approximately 333 MHz. In such an embodiment, the transmitter FRL resampler 204 may use the transmitter FRL data valid signal circuitry 208, which may be set to 8/9ths, to receive initially processed data from the transmitter FRL processing block 202 at the FRL clock frequency. This is because although the transmitter clock being received by the transmitter FRL resampler 204 may be 375 MHz, the transmitter FRL resampler 204 may receive the initially processed data from the transmitter FRL processing block 202 at approximately 333 MHz because the data may be valid approximately 88.88% of the time and 333 MHz is approximately 88.88% of 375 MHz. Again, it may be appreciated that in various embodiments, the frequency of the transmitter clock and/or the valid ratio of the transmitter FRL data valid signal circuitry 208 may be varying values in order to accommodate portions of the transmitter processing circuitry 106 with varying differences between respective operating clock frequencies.

Further, to accommodate components of the transmitter processing circuitry 106 that may provide resampled video data at an output clock frequency (e.g., the transmitter FRL resampler 204), transmitter output data valid signal circuitry 210 may be utilized. More specifically, the transmitter clock may be sent directly to the transmitter output data valid signal circuitry 210, which may be set to output a data valid signal a portion of the time corresponding to the ratio between the output clock frequency and the transmitter clock frequency. When the transmitter clock is sent directly to the transmitter output data valid signal circuitry 210, the transmitter output data valid signal circuitry 210 may output an effective output clock with a frequency suitable for operation of components of the transmitter processing circuitry 106 that may perform operations according to the output clock frequency. In such an embodiment, components of the transmitter processing circuitry that may perform operations according to the output clock frequency may perform such operations at the output clock frequency by receiving the effective output clock that has been output by the transmitter output data valid signal circuitry 210. For example, the transmitter clock frequency may be approximately 375 MHz while the output clock frequency is approximately 300 MHz. In the illustrated embodiment, the transmitter output data valid signal circuitry 210 may be set to ⅘ths such that the output data valid signal circuitry 210 may output a valid signal approximately 80% of the time. Because of this, the transmitter clock with a frequency of approximately 375 MHz may be received by the transmitter output data valid signal circuitry 210 and effectively converted by the output data valid signal circuity 210 into the effective output clock with a frequency of approximately 300 MHz to be sent to the components of the transmitter processing circuitry 106 that may perform operations according to the output clock frequency.

In various embodiments, the transmitter FRL data valid signal circuitry 208 and the transmitter output data valid signal circuitry 210 may be set to any ratio to accommodate portions of the transmitter processing circuitry 106 with varying operating clock frequencies. Further, in certain embodiments, the transmitter clock may originally have a frequency that corresponds with the FRL frequency and/or the output clock frequency. In such instances, the transmitter FRL data valid signal circuitry 208, the transmitter output data valid signal circuitry 210, or both may be omitted.

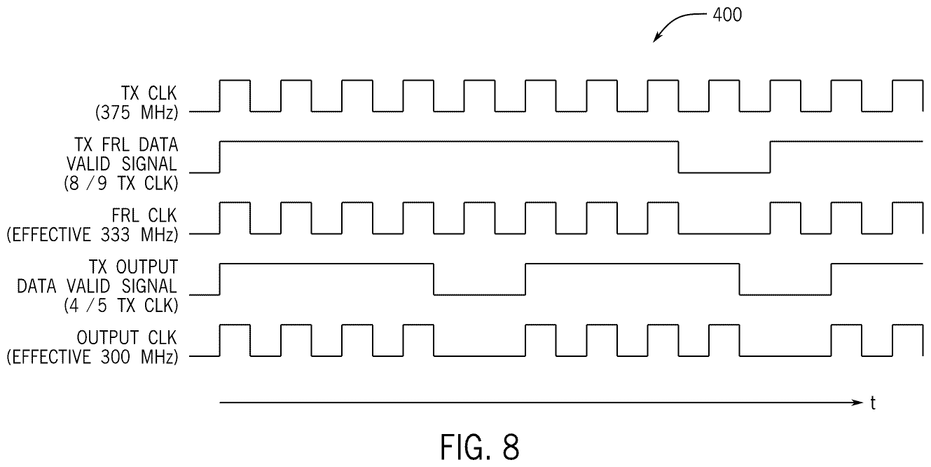

FIG. 8 is a transmitter timing diagram 400 of the transmitter clock, the valid output ratio of the transmitter FRL data valid signal circuitry 208, the effective FRL clock, the valid output ratio of the transmitter output data valid signal circuitry 210, and the effective output clock of FIG. 7, in accordance with an embodiment of the present disclosure. As depicted, the transmitter clock generated from the PLL 52 may have a frequency of 375 MHz. As further illustrated, the transmitter FRL data valid circuitry 208 may output a signal that is valid 8/9ths of the time. When the transmitter clock is effectively gated by the transmitter FRL data valid circuitry 208 as described above, the transmitter clock frequency may be effectively converted into the depicted effective FRL clock frequency. More specifically, in the illustrated embodiment, the transmitter clock frequency may be effectively reduced by approximately 11.111% to an effective FRL clock frequency of 333 MHz. This effective FRL clock frequency may be an averaged match of the FRL clock frequency compatible for operation of at least a portion of the transmitter processing circuitry 106, as described with reference to FIG. 7. Thus, the FRL clock may be effectively derived from the transmitter clock.

As further depicted, the transmitter output data valid signal circuitry 210 may output a signal that is valid ⅘ths of the time. When the transmitter clock is effectively gated by the transmitter output data valid signal circuitry 210 as described above, the transmitter clock frequency may be effectively transformed into the depicted effective output clock frequency. More specifically, in the illustrated embodiment, the transmitter clock frequency may be effectively reduced by approximately 20% to an effective output clock frequency of 300 MHz. This effective output clock frequency may be an averaged match of the output clock frequency prescribed by a portion of the transmitter processing circuitry 106 to output resampled data at. Thus, the output clock may be effectively derived from the transmitter clock.

It may be appreciated that the transmitter clock frequency, the effective FRL clock frequency, the effective output clock frequency, the transmitter FRL data valid signal circuitry 208 valid output ratio, and the transmitter output data valid signal circuitry 210 valid output ratio depicted in FIG. 8 are merely provided as an example. As such, the transmitter clock frequency may be any suitable frequency for deriving an effective FRL clock and an effective output clock via data valid signaling. The effective FRL clock frequency may be any suitable frequency for operation of components of the transmitter processing circuitry 106 that may perform operations according to an FRL clock. The effective output clock frequency may be any suitable frequency for output of resampled video data by a portion of the transmitter processing circuitry 106 that may provide resampled video data at an output clock frequency. Additionally, the transmitter FRL data valid signal circuitry 208 valid output ratio may be any suitable ratio for effective clock frequency conversion between any transmitter clock frequency and any effective FRL clock frequency compatible for components of the transmitter processing circuitry 106 that may perform operations according to an FRL clock frequency. Further, the transmitter output data valid signal circuitry 210 valid output ratio may be any suitable ratio for effective clock frequency conversion between any transmitter clock frequency and any effective output clock frequency compatible for components of the transmitter processing circuitry 106 that may provide resampled video data at an output clock frequency.

Further, it may be appreciated that the use of the word “effective” when describing the effective FRL clock and the effective output clock that may be derived from the transmitter clock via the transmitter FRL data valid signal circuitry 208 and the transmitter output data valid signal circuitry 210, respectively, is merely intended to illustrate how the data valid signaling adjusts the data rate of data flowing into and out of components of the transmitter processing circuitry 106 so that such components may operate according to prescribed operating speeds.

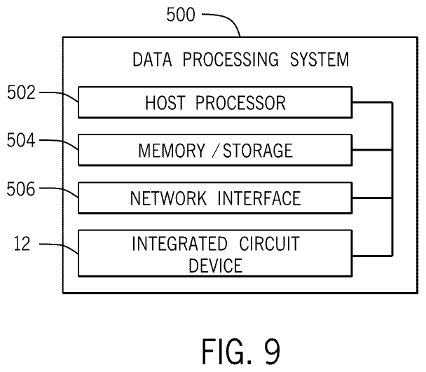

The integrated circuit device 12 discussed above may be a component included in a data processing system, such as a data processing system 500, shown in FIG. 9. The data processing system 500 may include the integrated circuit device 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . . ” or “step for [perform]ing [a function]. . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENTS 1. An integrated circuit device comprising: receiver processing circuitry configured to process the data into video data comprising: a first component of a fixed rate link (FRL) path configured to operate according to a first clock frequency at an input side of the first component and a second clock frequency corresponding to a receiver clock derived from a first-phase locked loop (PLL) at an output side of the first component, wherein the input side of the first component and the output side of the first component both receive the receiver clock, and wherein the input side of the first component is able to operate according to the first clock frequency by using the receiver clock and data valid signaling; and video data processing or storage circuitry configured to use the video data.
EXAMPLE EMBODIMENT 2. The integrated circuit device of example embodiment 1, wherein the data valid signaling comprises providing a data valid signal to the first component of the FRL path when the FRL path is in use to control a data rate of data being input into the first component.
EXAMPLE EMBODIMENT 3. The integrated circuit device of example embodiment 1, further comprising one or more receiver DCFIFOs configured to operate according to the first clock frequency, wherein the one or more receiver DCFIFOs receive the receiver clock, and wherein the first clock frequency is effectively derived from the receiver clock via data valid signaling.
EXAMPLE EMBODIMENT 4. The integrated circuit device of example embodiment 1, wherein the second clock frequency is approximately 333 MHz.
EXAMPLE EMBODIMENT 5. The integrated circuit device of example embodiment 1, wherein the first clock frequency is lower than the second clock frequency.
EXAMPLE EMBODIMENT 6. The integrated circuit device of example embodiment 1, wherein the receiver processing circuitry is configured to process the data into the video data based on a High-Definition Multimedia Interface (HDMI) protocol that specifies the second clock frequency.
EXAMPLE EMBODIMENT 7. The integrated circuit device of example embodiment 6, wherein the receiver processing circuitry is configured to process the data into the video data based on an HDMI 2.1 protocol.
EXAMPLE EMBODIMENT 8. The integrated circuit device of example embodiment 1, wherein the first clock frequency is approximately 300 MHz.
EXAMPLE EMBODIMENT 9. The integrated circuit device of example embodiment 1, wherein the receiver processing circuitry comprises a component of a system design configuration of a programmable logic device and the integrated circuit device comprises the programmable logic device.
EXAMPLE EMBODIMENT 10. Video data transmission circuitry comprising: a first data valid signal circuit configured to receive a transmitter clock from a physical transmitter circuit and generate a first data valid signal; and video data processing circuitry configured to perform video data processing according to a video protocol specifying operation at a fixed rate link (FRL) clock frequency, wherein the first video data processing circuit is configured to use the transmitter clock and the first data valid signal to operate at the FRL clock frequency.
EXAMPLE EMBODIMENT 11. The video data transmission circuitry of example embodiment 10, wherein the video data processing circuitry comprises: an initial processing circuit configured to receive video data according to a video clock and provide initially processed video data at the FRL clock frequency; and a subsequent processing circuit configured to receive the initially processed video data according to the FRL clock frequency and provide resampled video data at an output clock frequency.
EXAMPLE EMBODIMENT 12. The video data transmission circuitry of example embodiment 10, wherein the video data processing circuitry is configured to perform video data processing based on a High-Definition Multimedia Interface (HDMI) protocol that specifies the FRL clock frequency.
EXAMPLE EMBODIMENT 13. The video data transmission circuitry of example embodiment 10, wherein the FRL clock frequency is approximately 333 MHz.
EXAMPLE EMBODIMENT 14. The video data transmission circuitry of example embodiment 10, wherein the transmitter clock has a frequency higher than the FRL clock frequency.
EXAMPLE EMBODIMENT 15. The video data transmission circuitry of example embodiment 12, wherein the video data processing circuitry is configured to perform video data processing based on an HDMI 2.1 protocol.
EXAMPLE EMBODIMENT 16. One or more tangible, non-transitory, machine-readable media comprising a system design configuration for an integrated circuit device that, when programmed into the integrated circuit device, comprises: a first data valid signal circuit configured to receive a transmitter clock from a physical transmitter circuit and generate a first data valid signal; and video data processing circuitry configured to perform video data processing according to a video protocol specifying operation at a fixed rate link (FRL) clock frequency, wherein the first video data processing circuit is configured to use the transmitter clock and the first data valid signal to operate at the FRL clock frequency.
EXAMPLE EMBODIMENT 17. The one or more tangible, non-transitory, machine-readable media of example embodiment 16, wherein a first circuit of the video data processing circuitry is configured to receive video data according to a video clock and provide initially processed video data at the FRL clock frequency.
EXAMPLE EMBODIMENT 18. The one or more tangible, non-transitory, machine-readable media of example embodiment 17, wherein a second circuit of the video data processing circuitry is configured to receive the initially processed video data according to the FRL clock frequency and provide resampled video data at an output clock frequency.
EXAMPLE EMBODIMENT 19. The one or more tangible, non-transitory, machine-readable media of example embodiment 16, wherein the video protocol comprises a High-Definition Multimedia Interface (HDMI) protocol.
EXAMPLE EMBODIMENT 20. The one or more tangible, non-transitory, machine-readable media of example embodiment 16, wherein the transmitter clock has a frequency higher than the FRL clock frequency.

What is claimed is:

1. An integrated circuit device comprising:
physical receiver circuitry configured to receive data;
receiver processing circuitry configured to process the data into video data comprising:
a first component of a fixed rate link (FRL) path configured to operate according to a first clock frequency at an input side of the first component and a second clock frequency corresponding to a receiver clock derived from a first-phase locked loop (PLL) at an output side of the first component, wherein the input side of the first component and the output side of the first component both receive the receiver clock, and wherein the input side of the first component is able to operate according to the first clock frequency by using the receiver clock and data valid signaling; and
video data processing or storage circuitry configured to use the video data.

2. The integrated circuit device of claim 1, wherein the data valid signaling comprises providing a data valid signal to the first component of the FRL path when the FRL path is in use to control a data rate of data being input into the first component.

3. The integrated circuit device of claim 1, further comprising one or more receiver DCFIFOs configured to operate according to the first clock frequency, wherein the one or more receiver DCFIFOs receive the receiver clock, and wherein the first clock frequency is effectively derived from the receiver clock via data valid signaling.

4. The integrated circuit device of claim 1, wherein the second clock frequency is approximately 333 MHz.

5. The integrated circuit device of claim 1, wherein the first clock frequency is lower than the second clock frequency.

6. The integrated circuit device of claim 1, wherein the receiver processing circuitry is configured to process the data into the video data based on a High-Definition Multimedia Interface (HDMI) protocol that specifies the second clock frequency.

7. The integrated circuit device of claim 6, wherein the receiver processing circuitry is configured to process the data into the video data based on an HDMI 2.1 protocol.

8. The integrated circuit device of claim 1, wherein the first clock frequency is approximately 300 MHz.

9. The integrated circuit device of claim 1, wherein the receiver processing circuitry comprises a component of a system design configuration of a programmable logic device and the integrated circuit device comprises the programmable logic device.

10. Video data transmission circuitry comprising:
a first data valid signal circuit configured to receive a transmitter clock from a physical transmitter circuit and generate a first data valid signal; and
video data processing circuitry configured to perform video data processing according to a video protocol specifying operation at a fixed rate link (FRL) clock frequency, wherein the first video data processing circuit is configured to use the transmitter clock and the first data valid signal to operate at the FRL clock frequency.

11. The video data transmission circuitry of claim 10, wherein the video data processing circuitry comprises:
an initial processing circuit configured to receive video data according to a video clock and provide initially processed video data at the FRL clock frequency; and
a subsequent processing circuit configured to receive the initially processed video data according to the FRL clock frequency and provide resampled video data at an output clock frequency.

12. The video data transmission circuitry of claim 10, wherein the video data processing circuitry is configured to perform video data processing based on a High-Definition Multimedia Interface (HDMI) protocol that specifies the FRL clock frequency.

13. The video data transmission circuitry of claim 10, wherein the FRL clock frequency is approximately 333 MHz.

14. The video data transmission circuitry of claim 10, wherein the transmitter clock has a frequency higher than the FRL clock frequency.

15. The video data transmission circuitry of claim 12, wherein the video data processing circuitry is configured to perform video data processing based on an HDMI 2.1 protocol.

16. One or more tangible, non-transitory, machine-readable media comprising a system design configuration for an integrated circuit device that, when programmed into the integrated circuit device, comprises:
a first data valid signal circuit configured to receive a transmitter clock from a physical transmitter circuit and generate a first data valid signal; and
video data processing circuitry configured to perform video data processing according to a video protocol specifying operation at a fixed rate link (FRL) clock frequency, wherein the first video data processing circuit is configured to use the transmitter clock and the first data valid signal to operate at the FRL clock frequency.

17. The one or more tangible, non-transitory, machine-readable media of claim 16, wherein a first circuit of the video data processing circuitry is configured to receive video data according to a video clock and provide initially processed video data at the FRL clock frequency.

18. The one or more tangible, non-transitory, machine-readable media of claim 17, wherein a second circuit of the video data processing circuitry is configured to receive the initially processed video data according to the FRL clock frequency and provide resampled video data at an output clock frequency.

19. The one or more tangible, non-transitory, machine-readable media of claim 16, wherein the video protocol comprises a High-Definition Multimedia Interface (HDMI) protocol.

20. The one or more tangible, non-transitory, machine-readable media of claim 16, wherein the transmitter clock has a frequency higher than the FRL clock frequency.
